(19) United States
(12) Patent Application Publication
(10) Pub. No.: US 2026/0164730 A1
(43) Pub. Date: Jun. 11, 2026

(54) GROUP III-V POWER SEMICONDUCTOR DEVICE AND METHOD OF MANUFACTURING SAME

(71) Applicant: DB HiTek Co., Ltd., Bucheon-si (KR)

(72) Inventors: Jun Hyeok LEE, Eumseong-gun (KR); Woo Chul JEON, Eumseong-gun (KR); Jong Hyun LEE, Eumseong-gun (KR); Ji Houn JUNG, Eumseong-gun (KR); Hee Sub LEE, Eumseong-gun (KR); Min Su CHO, Eumseong-gun (KR); Dong Hyeok SON, Eumseong-gun (KR); Ung Bi SON, Eumseong-gun (KR)

(21) Appl. No.: 19/081,444

(22) Filed: Mar. 17, 2025

(30) Foreign Application Priority Data
Dec. 11, 2024 (KR) 10-2024-0183578

(51) Int. Cl. H10D 62/10; H10D 30/01; H10D 30/47; H10D 62/60; H10D 62/824; H10D 64/00

(52) U.S. Cl. CPC H10D 62/102; H10D 30/015; H10D 30/475; H10D 62/124; H10D 62/60; H10D 62/824; H10D 64/112

(57) ABSTRACT

Proposed are a group III-V power semiconductor device and a method of manufacturing the same. More particularly, proposed are a group III-V power semiconductor device in which an electric field relaxation layer is formed on a barrier layer or channel layer, between a capping layer and a drain electrode, thereby relaxing the peak electric field between the drain electrode and a gate electrode on the capping layer, and a method of manufacturing the same.

### CROSS REFERENCE TO RELATED APPLICATION

The present application claims priority to Korean Patent Application No. 10-2024-0183578, filed Dec. 11, 2024, the entire contents of which is incorporated herein for all purposes by this reference.

### BACKGROUND

### Technical Field

The present disclosure relates to a group III-V power semiconductor device and a method of manufacturing the same. More particularly, the present disclosure relates to a group III-V power semiconductor device in which an electric field relaxation layer is formed on a barrier layer or channel layer, between a capping layer and a drain electrode, thereby relaxing the peak electric field between the drain electrode and a gate electrode on the capping layer, and a method of manufacturing the same.

### Description of the Related Art

Nitride-based semiconductors are being applied to high-withstand voltage and high-power semiconductor devices through high electron saturation velocity and wide band gap characteristics. In particular, gallium nitride (GaN) has high breakdown field characteristics and wide band gap characteristics compared to silicon and gallium arsenide (GaAs) and thus exhibits excellent breakdown voltage characteristics when applied to transistors.

In addition, GaN-based devices have high electron mobility and electron saturation velocity compared to silicon-based devices, which are currently commonly available, and thus can exhibit high frequency characteristics. In addition, the application of such high electron mobility to GaN-based devices allows for improved on-resistance characteristics, thereby enabling the implementation of low-loss switching devices.

As described above, GaN-based field effect transistors (FETs) are sufficiently advantageous as devices that require high-frequency and high-power characteristics, so ongoing research is in progress. While these GaN-based FETs have been widely studied and developed over the years, there are still several issues regarding device reliability that need to be addressed.

To deplete a two-dimensional electron gas (2DEG) layer in a channel layer, such a nitride-based semiconductor device may use a structure in which a p-GaN layer is stacked on a barrier layer on the channel layer. In addition, to reduce the resistance of the 2DEG layer, a method of increasing the Al composition in the barrier layer, which is an AlGaN layer, or increasing the vertical thicknesses of the barrier layer can, for example, be applied. However, due to the limitations of the current technology in increasing the hole concentration in the p-GaN layer, increasing the Al composition in the barrier layer to obtain a certain level of threshold voltage or higher is challenging. Furthermore, when the vertical thicknesses of the barrier layer are formed to a certain level or larger, the thickness of the barrier layer immediately below the p-GaN layer becomes large, so the normally-off operation of the nitride-based power semiconductor device may not work.

When the resistance of such a 2DEG layer is not reduced, the high resistance of the 2DEG layer results in increased on-resistance of the device, leading to poor operational characteristics thereof, which may cause overall system performance degradation.

To solve such a problem, the inventors of the present disclosure have proposed a novel group III-V power semiconductor device and a method of manufacturing the same, the contents of which will be described in detail later.

### DOCUMENT OF RELATED ART

### Patent Document

Korean Patent Application Publication No. 10-2020-0068745 “High-Electron-Mobility Transistor”

### SUMMARY

The present disclosure, which has been devised to address the above-described issues in the related art, aims to provide a group III-V power semiconductor device in which an electric field relaxation layer is formed on a barrier layer or channel layer, between a capping layer and a drain electrode, thereby relaxing the peak electric field between the drain electrode and a gate electrode on the capping layer, and a method of manufacturing the same.

In addition, the present disclosure aims to provide a group III-V power semiconductor device in which an electric field relaxation layer is formed on a barrier layer or channel layer, thereby reducing the resistance of a 2DEG layer below the electric field relaxation layer so that the on-resistance characteristics of the device are improved, and a method of manufacturing the same.

In addition, the present disclosure aims to provide a group III-V power semiconductor device in which the electric field described above is formed, thereby mitigating the electron capture on a side adjacent to a barrier layer and, accordingly, minimizing the memory effect of the device, and a method of manufacturing the same.

In addition, the present disclosure aims to provide a group III-V power semiconductor device in which a field plate having a shape corresponding to that of an electric field relaxation layer having a stepped cross-sectional structure is formed, thereby further mitigating the electric field concentration at an edge part of a gate electrode, and a method of manufacturing the same.

The present disclosure may be implemented by embodiments having the following configurations to achieve the above-described objectives.

In one embodiment of the present disclosure, a group III-V power semiconductor device, according to the present disclosure, is characterized by including: a substrate; a channel layer on the substrate; a barrier layer on the channel layer; a capping layer on the barrier layer; a gate electrode on the capping layer; a source electrode and a drain electrode that are disposed while being spaced from each other with the gate electrode disposed therebetween; and an electric field relaxation layer on the barrier layer along a first direction, between the capping layer and the drain electrode.

In another embodiment of the present disclosure, the group III-V power semiconductor device, according to the present disclosure, is characterized in that the electric field relaxation layer and the barrier layer are made of the same components.

In a further embodiment of the present disclosure, the group III-V power semiconductor device, according to the present disclosure, is characterized in that the electric field relaxation layer and the barrier layer are made of the same components with the same composition ratio.

In a further embodiment of the present disclosure, the group III-V power semiconductor device, according to the present disclosure, is characterized in that the electric field relaxation layer includes: a first relaxation layer on the barrier layer; and a second relaxation layer on the first relaxation layer.

In a further embodiment of the present disclosure, the group III-V power semiconductor device, according to the present disclosure, is characterized in that the first relaxation layer has one side wall adjacent to the gate electrode, the side wall not being disposed in the same plane as one side wall of the second relaxation layer corresponding thereto.

In a further embodiment of the present disclosure, the group III-V power semiconductor device, according to the present disclosure, is characterized in that the electric field relaxation layer has one side part having a stepped cross-sectional shape.

In a further embodiment of the present disclosure, the group III-V power semiconductor device, according to the present disclosure, is characterized in that the electric field relaxation layer is formed through a selective area regrowth (SAG) process.

In a further embodiment of the present disclosure, the group III-V power semiconductor device, according to the present disclosure, is characterized by further including: an insulation film covering the capping layer and the electric field relaxation layer; and a field plate on the insulation film.

In a further embodiment of the present disclosure, the group III-V power semiconductor device, according to the present disclosure, is characterized in that the field plate has a side adjacent to the gate electrode, the side having a stepped cross-sectional structure.

In a further embodiment of the present disclosure, a group III-V power semiconductor device, according to the present disclosure, is characterized by including: a substrate; a channel layer on the substrate; a barrier layer on the channel layer, the barrier layer including a material that differs from that of the channel layer; a capping layer on the barrier layer; a gate electrode on the capping layer; a source electrode and a drain electrode that are disposed while being spaced from each other with the gate electrode disposed therebetween; and an electric field relaxation layer between the barrier layer and the drain electrode.

In a further embodiment of the present disclosure, the group III-V power semiconductor device, according to the present disclosure, is characterized in that the electric field relaxation layer has a side that is disposed at the same height as the barrier layer.

In a further embodiment of the present disclosure, the group III-V power semiconductor device, according to the present disclosure, is characterized in that the electric field relaxation layer has a side that is disposed higher than the barrier layer.

In a further embodiment of the present disclosure, the group III-V power semiconductor device, according to the present disclosure, is characterized in that the electric field relaxation layer has a stepped part on one side of a top surface thereof.

In a further embodiment of the present disclosure, the group III-V power semiconductor device, according to the present disclosure, is characterized in that the electric field relaxation layer includes components that differ from those of the barrier layer.

In a further embodiment of the present disclosure, the group III-V power semiconductor device, according to the present disclosure, is characterized in that the electric field relaxation layer and the barrier layer are made of the same components with different composition ratios.

In a further embodiment of the present disclosure, the group III-V power semiconductor device, according to the present disclosure, is characterized in that the electric field relaxation layer is disposed even between the barrier layer and the source electrode.

In one embodiment of the present disclosure, a method of manufacturing a group III-V power semiconductor device, according to the present disclosure, is characterized by including the following steps: sequentially forming a buffer layer, a channel layer, and a barrier layer on a substrate; forming a capping layer doped with a first conductivity type on the barrier layer; forming an electric field relaxation layer on the barrier layer, between the capping layer and a drain electrode; forming a source electrode and the drain electrode that are spaced from each other, with the capping layer and the electric field relaxation layer disposed therebetween; and forming a gate electrode on the capping layer.

In another embodiment of the present disclosure, the method of manufacturing the group III-V power semiconductor device, according to the present disclosure, is characterized in that the electric field relaxation layer includes Al.

In a further embodiment of the present disclosure, the method of manufacturing the group III-V power semiconductor device, according to the present disclosure, is characterized in that the step of forming the electric field relaxation layer includes the following steps: forming a first mask pattern on the barrier layer, the first mask pattern including an insulation film; forming a first relaxation layer by performing an SAG process; and removing the first mask pattern.

In a further embodiment of the present disclosure, the method of manufacturing the group III-V power semiconductor device, according to the present disclosure, is characterized in that the step of forming the electric field relaxation layer further includes the following steps: forming a second mask pattern on the barrier layer so that at least one side of a top surface of the first relaxation layer is exposed; forming a second relaxation layer on the first relaxation layer by performing an SAG process; and removing the second mask pattern, and the electric field relaxation layer has one side having a stepped cross-sectional shape.

The present disclosure has the following effects based on the above-described configurations.

The present disclosure has an effect of forming an electric field relaxation layer on a barrier layer or channel layer, between a capping layer and a drain electrode, thereby relaxing the peak electric field between the drain electrode and a gate electrode on the capping layer.

In addition, the present disclosure has an effect of forming an electric field relaxation layer on a barrier layer or channel layer, thereby reducing the resistance of a 2DEG layer below the electric field relaxation layer so that the on-resistance characteristics of the device are improved.

In addition, the present disclosure derives an effect of forming the electric field described above, thereby mitigating the electron capture on a side adjacent to a barrier layer and, accordingly, minimizing the memory effect of the device.

In addition, the present disclosure shows an effect of forming a field plate having a shape corresponding to that of an electric field relaxation layer having a stepped cross-sectional structure, thereby further mitigating the electric field concentration at an edge part of a gate electrode.

In the meantime, it is further stated that even when not explicitly mentioned herein, the effects hereinafter expected by the technical features of the present disclosure and potential effects thereof are treated as those described herein of the present disclosure.

### BRIEF DESCRIPTION OF THE DRAWINGS

FIG. 1 is a plan view illustrating a group III-V power semiconductor device according to a first embodiment of the present disclosure;

FIG. 2 is a cross-sectional view along the line AA′ illustrating the group III-V power semiconductor device based on FIG. 1;

FIG. 3 is a cross-sectional view along the line AA′ illustrating a multilayer stacked structure of an electric field relaxation layer based on FIG. 1;

FIG. 4 is a cross-sectional view illustrating a group III-V power semiconductor device according to a second embodiment of the present disclosure;

FIGS. 5 to 13 are cross-sectional views illustrating a method of manufacturing the group III-V power semiconductor device according to the first embodiment of the present disclosure; and

FIGS. 14 to 19 are cross-sectional views illustrating a method of manufacturing the group III-V power semiconductor device according to the second embodiment of the present disclosure.

### DETAILED DESCRIPTION

Hereinafter, embodiments of the present disclosure will be described in more detail with reference to the attached drawings. The embodiments of the present disclosure may be modified in various forms, and the scope of the present disclosure should not be construed as being limited to the following embodiments but should be construed on the basis of the appended claims. In addition, these embodiments are only provided for reference to more completely describe the present disclosure to those of ordinary skill in the art to which the present disclosure pertains.

Hereinafter, it should be noted that when one component (or layer) is described as being disposed on another component (or layer), one component may be disposed directly on another component, or another component(s) or layer(s) may be disposed between the components. In addition, when one component is expressed as being directly disposed on or above another component, no other component(s) are disposed between the components. Furthermore, being disposed “on”, “on an upper portion of”, “on a lower portion of”, “above”, “below”, “on one (first) side of”, or “on one side surface of” a component implies a relative positional relationship.

In addition, terms such as first, second, and the like may be used to describe various items, such as various elements, regions, and/or portions, but these items are not limited by such terms.

It should also be noted that when certain embodiments are implementable otherwise, certain processes may be performed in an order that differs from that described below. For example, two processes described sequentially may be substantially performed simultaneously or inversely.

Furthermore, a conductivity type or a doped region of components may be defined as “p-type” or “n-type” depending on the characteristics of main carriers, but this is only for the benefit of description, and the technical idea of the present disclosure is not limited as exemplified. For example, the more general term “first conductivity type” or “second conductivity type” will be used hereinafter for the “p-type” or “n-type”. In this case, the first conductivity type refers to the p-type, and the second conductivity type refers to the n-type.

It should also be understood that the terms “high concentration” and “low concentration” that express doping concentrations of impurity regions may refer to relative doping concentrations of one component and other components.

In a plan view illustrated, an x-axis direction is set as a “first direction”, while a y-axis direction is set as a “second direction”.

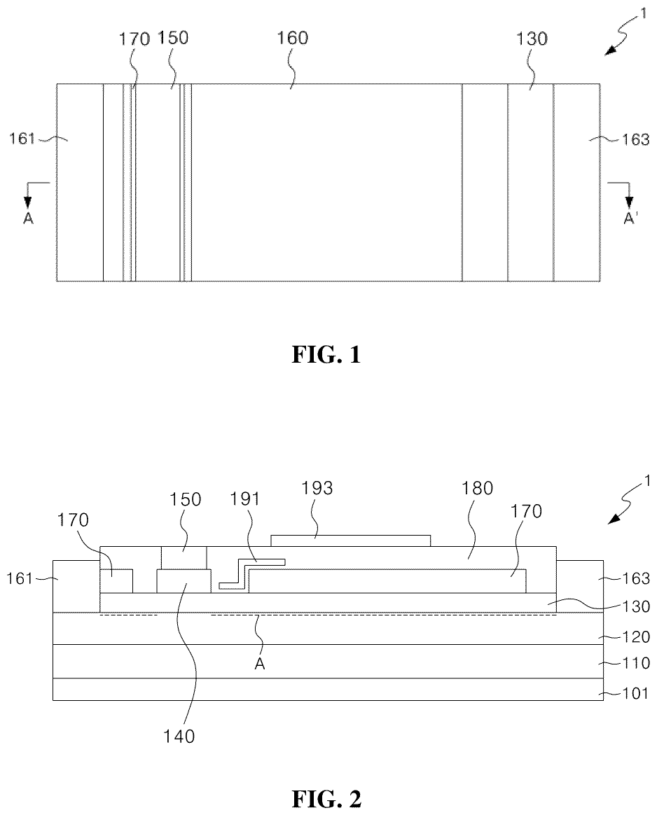

FIG. 1 is a plan view illustrating a group III-V power semiconductor device according to a first embodiment of the present disclosure, and FIG. 2 is a cross-sectional view along the line AA′ illustrating the group III-V power semiconductor device based on FIG. 1. It should be noted that in the plan view illustrated in FIG. 1, a first field plate, a second field plate, and an insulation film are omitted.

Hereinafter, a group III-V power semiconductor device 1, according to the first embodiment of the present disclosure, will be described in detail with reference to the attached drawings.

Referring to FIGS. 1 and 2, the present disclosure relates to the group III-V power semiconductor device 1. More particularly, the present disclosure relates to the group III-V power semiconductor device 1 in which an electric field relaxation layer 170 is formed on a barrier layer 130, between a capping layer 140 and a drain electrode 163, thereby relaxing the peak electric field between the drain electrode 163 and a gate electrode 150 on the capping layer 140.

First, the group III-V power semiconductor device 1, according to one embodiment of the present disclosure, may include a substrate 101. The substrate 101, which is a substrate for growth, may, for example, be a silicon substrate, but there are no limitations. Other examples thereof may include a sapphire substrate, a GaN substrate, or a SiC substrate. In the present disclosure, an example where the substrate 101 is a silicon substrate is to be described.

In addition, a buffer layer 110 may be formed on the substrate 101. The buffer layer 110 may be formed, for example, by growing AlN on the substrate 101 to a predetermined thickness. Alternatively, the buffer layer 110 may have a form in which a single layer of GaN or AlGaN or a composite layer of one or more of the foregoing GaN and AlGaN is grown, but there are no limitations. Such a buffer layer 110 may be a structure configured to prevent stress caused by differences in lattice constants and thermal expansion coefficients between the substrate 101 and a channel layer 120 to be described later. The buffer layer 110 may also be doped with impurities such as C and/or Fe.

The channel layer 120 is formed to have a predetermined thickness on the substrate 101, more preferably on the buffer layer 110, and may, for example, be made of a semiconductor layer based on a nitride such as GaN. In addition, the barrier layer 130 is formed to have a predetermined thickness on the channel layer 120 and may, for example, be a semiconductor layer based on a nitride such as AlGaN. Such channel layer 120 and barrier layer 130 are preferably formed of nitride-based semiconductor layers that differ from each other. In one example, the channel layer 120 and the barrier layer 130 may also include a material formed by a difference in composition ratio based on a combination of x and y in an AlₓIn_{y}Ga_{1-x-y}N material (x+y<1). In addition, the barrier layer 130 may include a material that has a wider band gap than that of the channel layer 120.

On the basis of such a structure, a 2DEG layer A may be formed near the interface between the channel layer 120 and the barrier layer 130. In this case, the density and mobility of the 2DEG layer A may be controlled by adjusting the Al and Ga contents in the barrier layer 130. The 2DEG layer A may be formed in the channel layer 120. In addition, to reduce the resistance of the 2DEG layer A, a method of increasing the Al composition in the barrier layer 130, which is an AlGaN layer, or increasing the vertical thicknesses of the barrier layer 130 may, for example, be adopted. However, when the vertical thickness of the barrier layer 130 is formed to a certain level or larger, there are limitations because the normally-off operation of the device 1 may not work.

In addition, the capping layer 140 may be formed on the barrier layer 130. The capping layer 140, which is configured to be formed between the barrier layer 130 and the gate electrode 150, preferably has a positive polarity, for example, of the first conductive type. When such a capping layer 140 is formed to a predetermined or larger thickness, the gate electrode 150 and the 2DEG layer A become more distant, resulting in a longer response time.

In contrast, when formed to a predetermined or smaller thickness, it is difficult to achieve the normally-off operation. Therefore, the thickness thereof is preferably formed at a suitable level, which is, for example, in the range of 10 nm to 1000 nm, but there are no limitations. In addition, the capping layer 140 may be formed by growing p-GaN and may, for example, be formed by doping GaN with Mg.

The gate electrode 150 may also be formed on the capping layer 140. The gate electrode 150 may, for example, be formed of a single layer or composite layer made of various metals, such as Ti and Pd. In addition, the gate electrode 150 is capable of normally-off operation. The depletion layer of such a gate electrode 150 may penetrate the barrier layer 130, reaching the channel layer 120 and thus blocking the 2DEG layer A.

In addition, a source electrode 161 and the drain electrode 163 may be formed on the barrier layer 130 while being spaced from each other. In some cases, the source electrode 161 and the drain electrode 163 may be formed such that the lower portions thereof are disposed in the barrier layer 130, on the interface between the barrier layer 130 and the channel layer 120, in the channel layer 120, or on the barrier layer 130. However, there are no particular limitations.

The source electrode 161 and the drain electrode 163 may be disposed in an active region while being spaced from each other with the gate electrode 150 disposed therebetween. Such source electrode 161 and drain electrode 163, which are ohmic contact regions, may, for example, have a square cross-sectional shape or a stepped cross-sectional shape. However, the scope of the present disclosure is not limited by any particular examples. In addition, the source electrode 161 and the drain electrode 163 may, for example, include a single layer or composite layer made of various metals capable of ohmic contact, such as Ti, Au, and Al. However, there are no particular limitations.

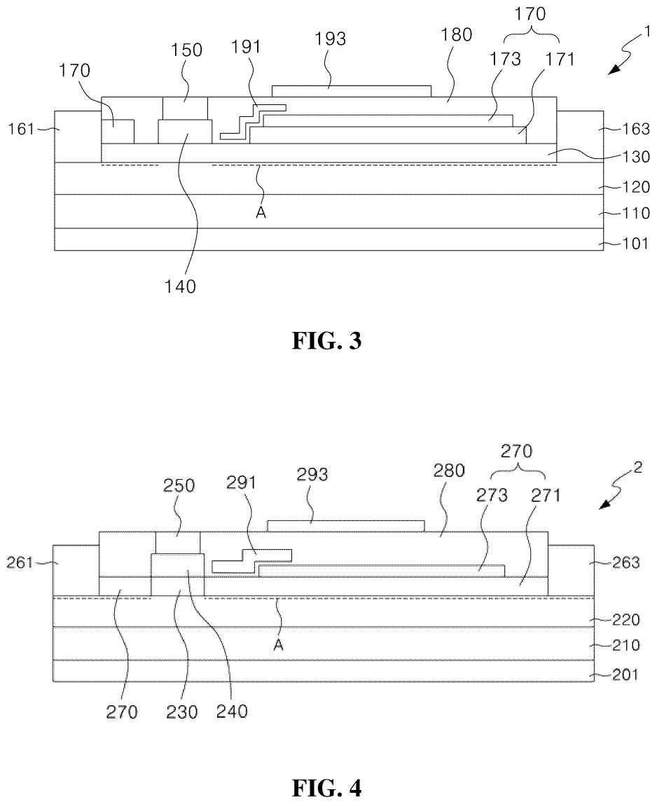

FIG. 3 is a cross-sectional view along the line AA′ illustrating a multilayer stacked structure of an electric field relaxation layer based on FIG. 1.

In addition, referring to FIGS. 1 to 3, the electric field relaxation layer 170 may be further formed on the barrier layer 130. The electric field relaxation layer 170 may be formed on the barrier layer 130, between the capping layer 140 and the drain electrode 163. In some cases, the electric field relaxation layer 170 may also be formed between the source electrode 161 and the capping layer 140, but the scope of the present disclosure is not limited thereto. When the electric field relaxation layer 170 is formed between the source electrode 161 and the capping layer 140, the resistance between the source electrode 161 and the gate electrode 150 can be reduced, thereby increasing the concentration of the 2DEG layer A.

The electric field relaxation layer 170 may also be formed such that a first end thereof along the first direction is in contact with or spaced from the capping layer 140. In addition, the electric field relaxation layer 170 may be formed such that a second end thereof along the first direction, the second end being opposite to the first end, is in contact with or spaced from the drain electrode 163. Furthermore, the electric field relaxation layer 170, when being elongated between the capping layer 140 and the drain electrode 163 along the first direction, may have a side that is elongated uninterruptedly or interrupted, but there are no particular limitations.

Such an electric field relaxation layer 170 may be formed as a single layer or a multilayer stacked structure on the barrier layer 130, between the capping layer 140 and the drain electrode 163. For example, a first relaxation layer 171 may be formed on the barrier layer 130, and a second relaxation layer 173 may be formed on the first relaxation layer 171. In addition, one or more additional relaxation layers may be further formed on the second relaxation layer 173 as needed.

When the electric field relaxation layer 170 is formed as the multilayer stacked structure, opposite ends, being first and second ends, along the first direction of the first relaxation layer 171 and those of the second relaxation layer 173 may each be aligned substantially in the same plane. Alternatively, at least one end along the first direction of the first relaxation layer 171 and that of the second relaxation layer 173 corresponding thereto may not be aligned in the same plane. In other words, the second end of the first relaxation layer 171 and that of the second relaxation layer 173 are not stacked in the same plane. Accordingly, a stepped structure may be formed at the second ends of the first relaxation layer 171 and the second relaxation layer 173. When forming the stepped structure at the second ends of the first relaxation layer 171 and the second relaxation layer 173, as described above, a first field plate 191, which will be described later, may be allowed to have a stepped cross-sectional shape.

The first field plate 191 formed in such a shape may have substantially the same effect as a multilayer stacked structure where field plates are stacked along the vertical direction. Thus, with the electric fields concentrated at each edge part of the bottom surface of the first field plate 191 having the stepped cross-sectional structure, the overall electric field distribution effect may be obtained between the gate electrode 150 and the drain electrode 163.

The electric field relaxation layer 170 described above may be formed by forming the capping layer 140 and then performing an SAG process. In one example, the electric field relaxation layer 170 may be formed by performing a chemical vapor deposition (CVD) process. For a detailed description, the electric field relaxation layer 170 may be formed by performing a hydride vapor phase epitaxy (HVPE) process, a metal-organic chemical vapor deposition (MOCVD) process, a molecular beam epitaxy (MBE) process, or the like. However, the scope of the present disclosure is not limited thereto.

In one example, the electric field relaxation layer 170 may include a material formed by a difference in composition ratio based on a combination of x and y in an AlₓIn_{y}Ga_{1-x-y}N material (x+y<1), and may have a composition ratio that is the same as or different from that of the barrier layer 130. However, there are no particular limitations. In another example, the electric field relaxation layer 170 may be an AlN layer. As described above, to reduce the resistance (or increase the concentration) of the 2DEG layer A, the method of increasing the Al composition in the barrier layer 130, which is an AlGaN layer, or increasing the vertical thicknesses of the barrier layer 130 may, for example, be adopted. In the latter case, the application thereof has limitations because the normally-off operation of the device 1 may not work when the vertical thicknesses of the barrier layer 130 are formed to a certain level or larger. To address such issues, the group III-V power semiconductor device 1, according to one embodiment of the present disclosure, is characterized in that the electric field relaxation layer 170 is additionally formed on the barrier layer 130. By forming the electric field relaxation layer 170 as described above, the effect that is substantially the same as that in the case of increasing the vertical thickness of the barrier layer 130 can be obtained.

In other words, the resistance of the 2DEG layer A below the electric field relaxation layer 170 can be reduced by the electric field relaxation layer 170. In addition, by relaxing the electric field applied between the gate electrode 150 and the drain electrode 163 and, accordingly, mitigating the electron capture on a side adjacent to the barrier layer 130, the memory effect of the device 1 can be minimized, thus preventing current collapse. Furthermore, the electric field relaxation layer 170 can reduce the resistance of the 2DEG layer A, thus improving the on-resistance characteristics of the device 1.

For the following description, an insulation film 180 may be formed on the barrier layer 130. The insulation film 180 may cover the electric field relaxation layer 170. Such an insulation film 180 may be made of an electrically insulating material and may include an oxide film, a nitride film, or an oxynitride film.

In addition, the first field plate 191 may further be formed in the insulation film 180. Such a first field plate 191 is preferably formed on a side adjacent to the gate electrode 150 and is more preferably formed between the gate electrode 150 and the drain electrode 163. The first field plate 191 is configured to relax the peak electric field between the gate electrode 150 and the drain electrode 163. Between the gate electrode 150 and the drain electrode 163, the electric field may be concentrated at the edge part of the gate electrode 150. Therefore, the first field plate 191 is preferably formed on the edge part of the gate electrode 150 on the side facing the drain electrode 163. In some cases, the first field plate 191 may also be formed on a side being in contact with the top surface of the electric field relaxation layer 170. Furthermore, the first field plate 191 may be formed such that the bottom surface thereof has a stepped cross-sectional structure. In one example, the bottom surface of the first field plate 191, on the side adjacent to the gate electrode 150, may have a stepped cross-sectional structure. Such a first field plate 191 may be electrically connected with the source electrode 161.

In addition, a second field plate 193 may further be formed on the insulation film 180, on the first field plate 191.

FIG. 4 is a cross-sectional view illustrating a group III-V power semiconductor device according to a second embodiment of the present disclosure.

Hereinafter, a group III-V power semiconductor device 2, according to the second embodiment of the present disclosure, will be described in detail with reference to the attached drawings.

Hereinafter, a group III-V power semiconductor device 2, according to the second embodiment of the present disclosure, will be described in detail with reference to the attached drawings. In the illustrated drawings, components that are substantially identical to those in the first embodiment are designated by changing the first digit of the reference numeral in the drawings from “1” to “2”, and for convenience, descriptions of duplicated components are to be omitted.

Referring to FIG. 4, a barrier layer 230 in the group III-V power semiconductor device 2, according to the second embodiment, may have a partially etched side. For a detailed description thereof, the barrier layer 230 is formed immediately below a capping layer 240 and may have a side to be removed between the capping layer 240 and a drain electrode 263 along the first direction. Alternatively, the barrier layer 230 may be left at a relatively thin thickness between the capping layer 240 and the drain electrode 263 along the first direction. In some cases, the barrier layer 230 may also have a side to be removed between the capping layer 240 and a source electrode 261.

In addition, an electric field relaxation layer 270 may be formed between the drain electrode 263 and the barrier layer 230 immediately below the capping layer 240, along the first direction. The electric field relaxation layer 270 may be formed substantially in the same manner as the electric field relaxation layer 170 according to the first embodiment, so the detailed descriptions thereof are to be omitted.

Furthermore, the electric field relaxation layer 270 may include a material formed by a difference in composition ratio based on a combination of x and y in an AlₓIn_{y}Ga_{1-x-y}N material. In this case, the electric field relaxation layer 270 may include components that differ from those of the barrier layer 230. In one example, the barrier layer 230 may be an AlN layer. Alternatively, the electric field relaxation layer 270 and the barrier layer 230 may be formed to be made of the same components with different composition ratios. In addition, a 2DEG layer A immediately below the electric field relaxation layer 270 may have a much higher concentration than the 2DEG layer A immediately below the capping layer 240.

Furthermore, the electric field relaxation layer 270 may have a top surface that is substantially level with the top surface of the barrier layer 230. Alternatively, the electric field relaxation layer 270 may have an uppermost part that is disposed higher than the top surface of the barrier layer 230. In the latter case, the electric field relaxation layer 270 may be formed such that the cross-sectional shape thereof has a multilayer stacked structure. To this end, the electric field relaxation layer 270 may include a first relaxation layer 271 and a second relaxation layer 273. The first relaxation layer 271 and the second relaxation layer 273 correspond to the first relaxation layer 171 and the second relaxation layer 173 according to the first embodiment, respectively, so the detailed descriptions thereof are to be omitted.

In addition, a first field plate 291 and a second field plate 293 may further be formed on the electric field relaxation layer 270.

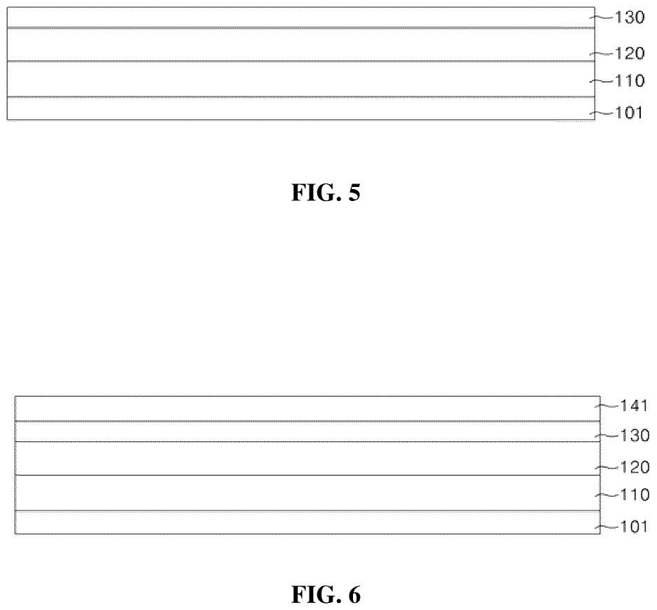

FIGS. 5 to 13 are cross-sectional views illustrating a method of manufacturing the group III-V power semiconductor device according to the first embodiment of the present disclosure.

Hereinafter, the method of manufacturing the group III-V power semiconductor device 1, according to the first embodiment of the present disclosure, will be described in detail with reference to the attached drawings.

Referring to FIG. 5, a buffer layer 110, a channel layer 120, and a barrier layer 130 may be first formed sequentially on a substrate 101. The substrate 101, which is a substrate for growth as described above, may be any one of a silicon substrate, a sapphire substrate, a GaN substrate, and a SiC substrate, but the description in the present disclosure is based on one example being a silicon substrate. The buffer layer 110 may be formed on the substrate 101 and under the channel layer 120, for example, by growing an AlN layer to a predetermined thickness. In addition, the channel layer 120 to be formed on the buffer layer 110 is a semiconductor layer based on a nitride such as GaN, and the barrier layer 130 is a semiconductor layer based on a nitride such as AlGaN. By electrons accumulated at the interface between the channel layer 120 and the barrier layer 130, a 2DEG layer A may be formed.

For a detailed description, piezoelectric polarization may occur at the interface between the channel layer 120 and the barrier layer 130, for example, due to differences in lattice constants between GaN and AlGaN. In this case, the piezoelectric polarization effect and the spontaneous polarization effect of the channel layer 120 and the barrier layer 130 may function, thereby generating two-dimensional electron gas with a high electron concentration at the interface between the two configurations.

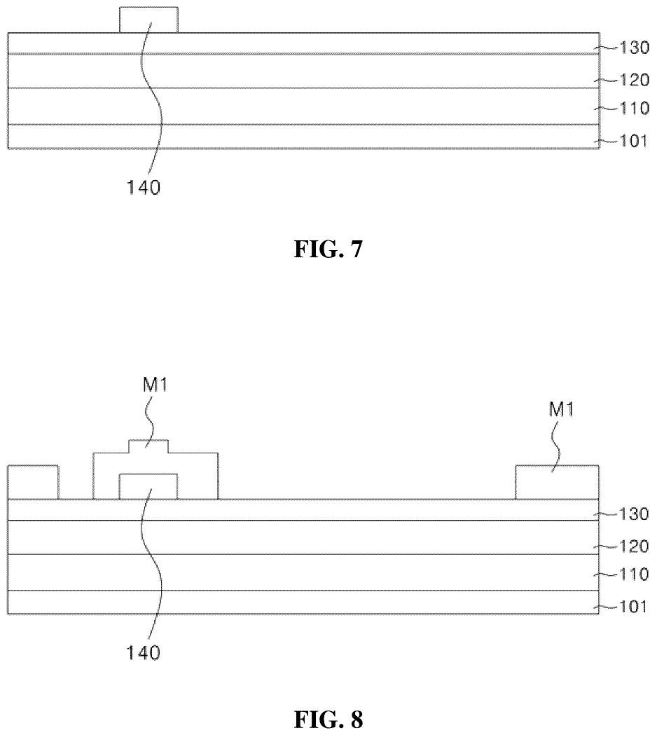

Then, a capping layer 140 may be formed on the barrier layer 130. Referring to FIG. 6, to this end, a doped layer 141, for example, in which a GaN layer is grown with the first conductivity type, may be first formed on the barrier layer 130. Referring to FIG. 7, a mask pattern (not shown) may be utilized thereafter to etch the doped layer 141, thereby completing the capping layer 140.

Referring to FIG. 8, a first mask pattern M1 may be then formed on the barrier layer 130. In this case, the first mask pattern M1 may include an oxide film, a nitride film, or an oxynitride film. The first mask pattern M1 may be formed such that the top surface of the barrier layer 130 on a side where an electric field relaxation layer 170 is to be formed is open while the capping layer 140 is covered.

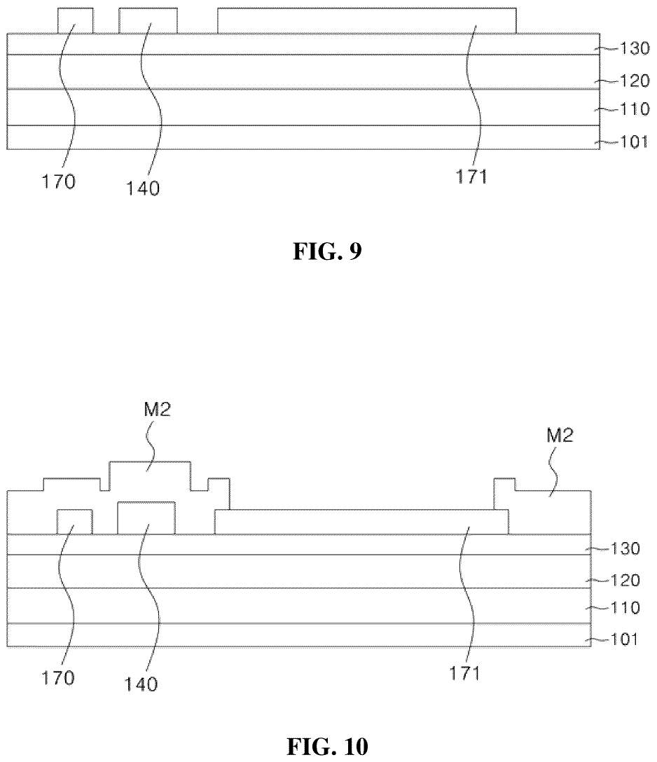

Referring to FIG. 9, the electric field relaxation layer 170 or a first relaxation layer 171 may be then formed on the barrier layer 130. The electric field relaxation layer 170 may be formed by performing an SAG process. The detailed description for the electric field relaxation layer 170 is covered by the description above. Subsequently, the first mask pattern M1 may be removed.

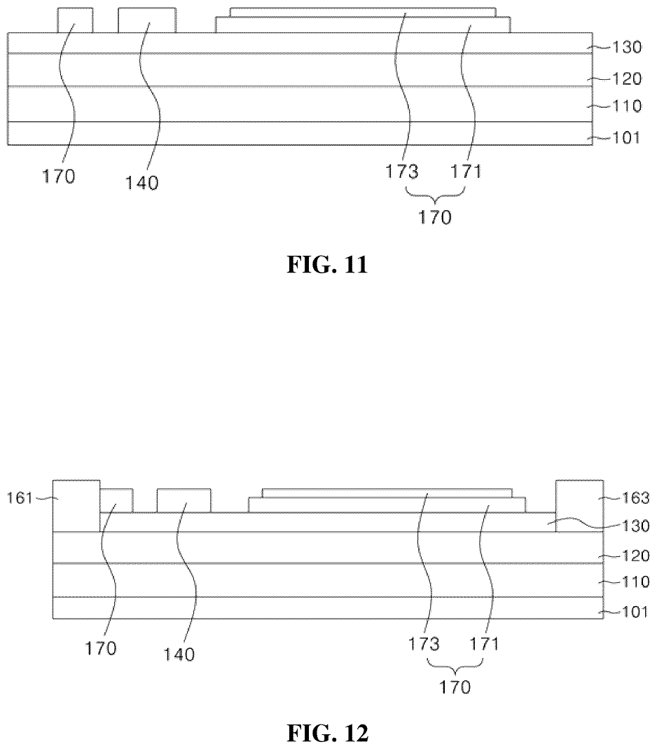

Alternatively, the electric field relaxation layer 170 may be formed as a multilayer stacked structure having a stepped cross-section. Referring to FIG. 10, a second mask pattern M2 may be formed again on the barrier layer 130. The second mask pattern M2 may be configured substantially in the same manner as the first mask pattern M1, but there are no particular limitations. The second mask pattern M2 may be formed such that at least one side of the top surface of the first relaxation layer 171 is exposed while the capping layer 140 is covered. Referring to FIG. 11, a second relaxation layer 173 may then be formed on the first relaxation layer 171. Subsequently, the second mask pattern M2 may be removed.

Referring to FIG. 12, a source electrode 161 and a drain electrode 163 may be formed thereafter along the first direction with the capping layer 140 disposed therebetween. The source electrode 161 and the drain electrode 163 may be formed by depositing a metal layer (not shown) and performing an etching process. In some cases, the source electrode 161 and the drain electrode 163 may be formed after depositing an insulation film 180, but there are no particular limitations.

Next, an insulation layer (not shown) may be formed on the barrier layer 130. The insulation layer (not shown) may be made of an electrically insulating material and may include an oxide film, a nitride film, or an oxynitride film. Subsequently, the insulation layer (not shown) may be etched so that at least one side of the top surface of the capping layer 140 is exposed. In this case, the top surfaces of the source electrode 161 and the drain electrode 163 may be exposed.

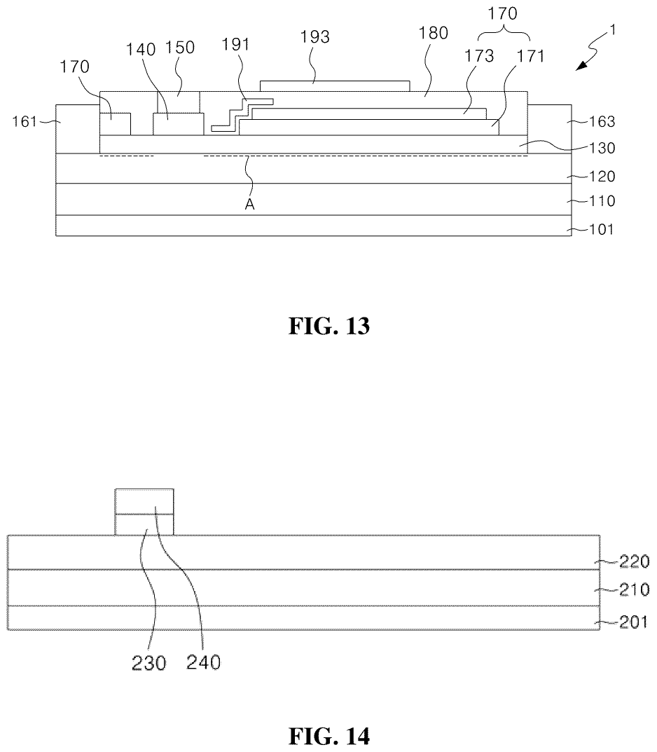

Referring to FIG. 13, a first field plate 191, a gate electrode 150, and a second field plate 193 may be formed thereafter through individual processes by depositing and etching a metal layer (not shown) on the insulation film 180.

FIGS. 14 to 19 are cross-sectional views illustrating a method of manufacturing the group III-V power semiconductor device according to the second embodiment of the present disclosure.

Hereinafter, the method of manufacturing the group III-V power semiconductor device 2, according to the second embodiment of the present disclosure, will be described in detail with reference to the attached drawings. In the following, only the process after the formation of a capping layer 240 will be described in detail.

Referring to FIG. 14, one side of a barrier layer 230, the side where the capping layer 240 is formed, may be first removed by etching or the like. In one example, the barrier layer 230 between the capping layer 240 and a side where a drain electrode 263 is to be formed along the first direction may be removed. Thus, the barrier layer 230 may only be disposed directly below the capping layer 240. In another example, the barrier layer 230 may be present or absent in a space between the capping layer 240 and a side where a source electrode 261 is to be formed along the first direction.

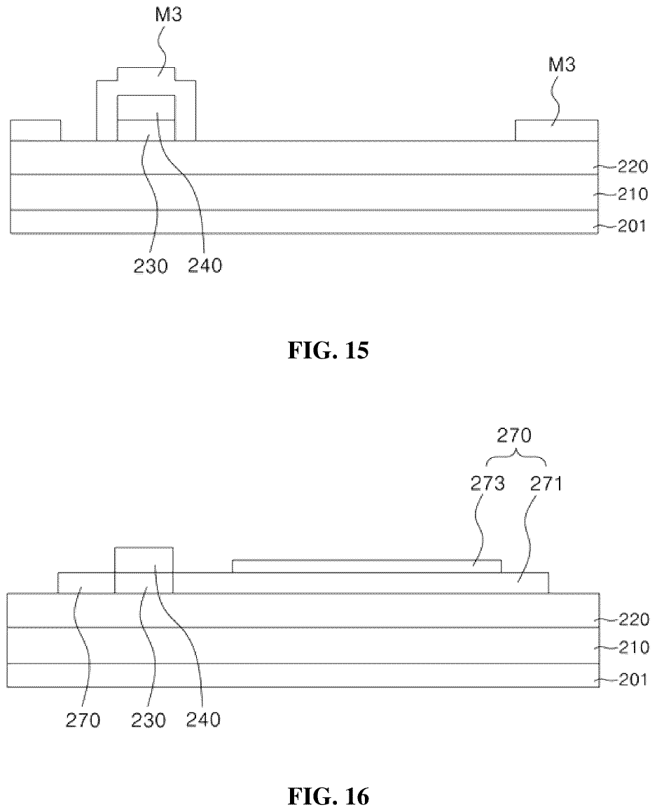

Referring to FIG. 15, a third mask pattern M3 may then be formed. The third mask pattern M3 may be configured substantially in the same manner as the first mask pattern M1, but there are no particular limitations. In addition, the third mask pattern M3 may be formed on the capping layer 240 as well as on a channel layer 220 on a side where the source electrode 261 and the drain electrode 263 are to be formed.

Referring to FIG. 16, an electric field relaxation layer 270 may be formed thereafter at the location where the capping layer 240 is removed. Subsequently, the processes described above may then be repeatedly performed to form the electric field relaxation layer 270 as a stacked structure having a stepped cross-sectional shape, the detailed description of which is to be omitted.

Next, the source electrode 261 and the drain electrode 263 are formed, which are covered by the descriptions for the corresponding configurations of the first embodiment.

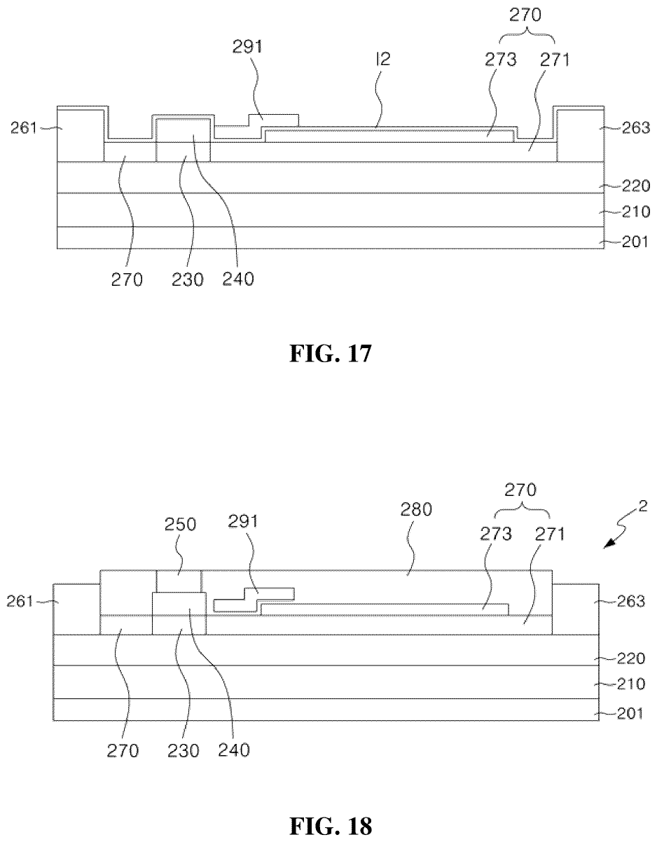

Referring to FIG. 17, a second insulation layer I2 may then be deposited on the electric field relaxation layer 270, followed by depositing and etching a metal layer (not shown) on the second insulation layer I2 to form a first field plate 291.

Referring to FIG. 18, a third insulation layer (not shown) may be deposited thereafter such that the first field plate 291 and the capping layer 240 are covered, while the third insulation layer on the capping layer 240 may be removed. In this case, the second insulation layer I2 and the third insulation layer on the source electrode 261 and the drain electrode 263 may also be removed. On the basis of the second insulation layer I2 and the third insulation layer, an insulation film 280 may be completed. Afterward, a metal layer (not shown) may be deposited and etched, thereby forming a gate electrode 250.

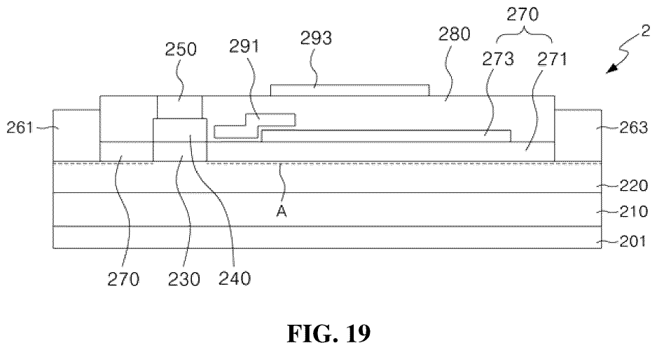

Referring to FIG. 19, a metal layer (not shown) may then be deposited on the insulation film 280 and then removed, thereby forming a second field plate 293.

The detailed description above is illustrative of the present disclosure. In addition, the description above shows and describes preferred embodiments of the present disclosure, and the present disclosure can be used in various other combinations, modifications, and environments. In other words, changes or modifications are possible within the scope of the concept of the disclosure disclosed herein, the scope equivalent to the written disclosure, and/or the scope of skill or knowledge in the art to which the present disclosure pertains. The above-described embodiments describe the best state for implementing the technical idea of the present disclosure, and various changes required in the specific application field and use of the present disclosure are possible. Therefore, the detailed description of the present disclosure above is not intended to limit the present disclosure to the embodiments disclosed herein.

What is claimed is:

1. A group III-V power semiconductor device comprising:
a substrate;
a channel layer disposed on the substrate;
a barrier layer disposed on the channel layer;
a capping layer disposed on the barrier layer;
a gate electrode disposed on the capping layer;
a source electrode and a drain electrode that are disposed while being spaced from each other with the gate electrode being disposed therebetween; and
an electric field relaxation layer disposed on the barrier layer along a first direction, between the capping layer and the drain electrode.

2. The group III-V power semiconductor device of claim 1, wherein the electric field relaxation layer comprises components that are same as components of the barrier layer.

3. The group III-V power semiconductor device of claim 2, wherein the electric field relaxation layer comprises the components in a composition ratio that is same as a composition ratio of the components of the barrier layer.

4. The group III-V power semiconductor device of claim 1,
wherein the electric field relaxation layer comprises:
a first relaxation layer disposed on the barrier layer; and
a second relaxation layer disposed on the first relaxation layer.

5. The group III-V power semiconductor device of claim 4, wherein the first relaxation layer has one side wall adjacent to the gate electrode, the one side wall of the first relaxation layer not being disposed in a same plane as one side wall of the second relaxation layer corresponding to the one side wall of the first relaxation layer.

6. The group III-V power semiconductor device of claim 4, wherein the electric field relaxation layer has one side part having a stepped cross-sectional shape.

7. The group III-V power semiconductor device of claim 1, wherein the electric field relaxation layer is formed through a selective area regrowth (SAG) process.

8. The group III-V power semiconductor device of claim 6, further comprising:
an insulation film covering the capping layer and the electric field relaxation layer; and
a field plate disposed on the insulation film.

9. The group III-V power semiconductor device of claim 8, wherein the field plate has a side adjacent to the gate electrode, the side having a stepped cross-sectional structure.

10. A group III-V power semiconductor device comprising:
a substrate;
a channel layer disposed on the substrate;
a barrier layer disposed on the channel layer, the barrier layer comprising a material that differs from a material of the channel layer;
a capping layer disposed on the barrier layer;
a gate electrode disposed on the capping layer;
a source electrode and a drain electrode that are disposed while being spaced from each other with the gate electrode being disposed therebetween; and
an electric field relaxation layer disposed between the barrier layer and the drain electrode.

11. The group III-V power semiconductor device of claim 10, wherein the electric field relaxation layer has a side that is disposed at a same height as a height of the barrier layer.

12. The group III-V power semiconductor device of claim 11, wherein the electric field relaxation layer has a side that is disposed higher than the barrier layer.

13. The group III-V power semiconductor device of claim 10, wherein the electric field relaxation layer has a stepped part on one side of a top surface thereof.

14. The group III-V power semiconductor device of claim 10, wherein the electric field relaxation layer comprises components that differ from components of the barrier layer.

15. The group III-V power semiconductor device of claim 10, wherein the electric field relaxation layer comprises components that are same as components of the barrier layer but with a composition ratio that differs from a composition ratio of the components of the barrier layer.

16. The group III-V power semiconductor device of claim 10, wherein the electric field relaxation layer is disposed between the barrier layer and the source electrode in addition to being disposed between the barrier layer and the drain electrode.

17. A method of manufacturing a group III-V power semiconductor device, the method comprising:
sequentially forming a buffer layer, a channel layer, and a barrier layer on a substrate;
forming a capping layer doped with a first conductivity type on the barrier layer;
forming an electric field relaxation layer on the barrier layer, between the capping layer and a drain electrode;
forming a source electrode and the drain electrode that are spaced from each other, with the capping layer and the electric field relaxation layer being disposed therebetween; and
forming a gate electrode on the capping layer.

18. The method of claim 17, wherein the electric field relaxation layer comprises Al.

19. The method of claim 17,
wherein the forming of the electric field relaxation layer comprises:
forming a first mask pattern on the barrier layer, the first mask pattern including an insulation film;
forming a first relaxation layer by performing an SAG process; and
removing the first mask pattern.

20. The method of claim 19,
wherein the forming of the electric field relaxation layer further comprises:
forming a second mask pattern on the barrier layer so that at least one side of a top surface of the first relaxation layer is exposed;
forming a second relaxation layer on the first relaxation layer by performing an SAG process; and
removing the second mask pattern, and
wherein the electric field relaxation layer has one side having a stepped cross-sectional shape.
